(19) United States
(12) Patent Application Publication
(10) Pub. No.: US 2016/0269662 A1
(43) Pub. Date: Sep. 15, 2016

(54) IMAGE SENSORS WITH INCREASED STACK HEIGHT FOR PHASE DETECTION PIXELS

(71) Applicant: SEMICONDUCTOR COMPONENTS INDUSTRIES, LLC, Phoenix, AZ (US)

(72) Inventors: Jason HEPPER, Meridian, ID (US); Ulrich BOETTIGER, Garden City, ID (US)

(73) Assignee: SEMICONDUCTOR COMPONENTS INDUSTRIES, LLC, Phoenix, AZ (US)

(21) Appl. No.: 14/656,400

(22) Filed: Mar. 12, 2015

(51) Int. Cl. H04N 5/369; H01L 27/146; H04N 9/04

(52) U.S. Cl. CPC H04N 5/3696; H04N 9/045; H01L 27/14621; H01L 27/14627; H01L 27/14645; H01L 27/14689; H01L 27/14685

(57) ABSTRACT

An image sensor may include a pixel array with a plurality of image pixels and a plurality of phase detection pixels. The plurality of phase detection pixels may have a greater stack height than the plurality of image pixels. Varying the stack height of pixels in the pixel array may enable the stack height of the image pixels to be optimized for gathering image data while the stack height of the phase detection pixels is optimized to gather phase detection data. A support structure may be used to increase the stack height of the phase detection pixels. The support structure may be formed over a color filter array or one or more microlenses. The support structure may include color filter elements to supplement or replace the color filter elements of the color filter array.

### BACKGROUND

This relates generally to imaging systems and, more particularly, to imaging systems with phase detection capabilities.

Modern electronic devices such as cellular telephones, cameras, and computers often use digital image sensors. Imager sensors (sometimes referred to as imagers) may be formed from a two-dimensional array of image sensing pixels. Each pixel receives incident photons (light) and converts the photons into electrical signals. Image sensors are sometimes designed to provide images to electronic devices using a Joint Photographic Experts Group (JPEG) format.

Some applications such as automatic focusing and three-dimensional (3D) imaging may require electronic devices to provide stereo and/or depth sensing capabilities. For example, to bring an object of interest into focus for an image capture, an electronic device may need to identify the distances between the electronic device and object of interest. To identify distances, conventional electronic devices use complex arrangements. Some arrangements require the use of multiple image sensors and camera lenses that capture images from various viewpoints. Other arrangements require the addition of lenticular arrays that focus incident light on sub-regions of a two-dimensional pixel array. Due to the addition of components such as additional image sensors or complex lens arrays, these arrangements lead to reduced spatial resolution, increased cost, and increased complexity.

Some electronic devices include both image pixels and phase detection pixels in a single image sensor. With this type of arrangement, a camera can use the on-chip phase detection pixels to focus an image without requiring a separate phase detection sensor. Typically, image pixels and phase detection pixels in a single image sensor will all have the same stack height, defined herein as the distance between a pixel's photodiode and the pixel's microlens. However, this arrangement can result in decreased data quality as image pixels and phase detection pixels require different stack heights for optimum data quality.

It would therefore be desirable to be able to provide improved phase detection pixel arrangements for image sensors.

### BRIEF DESCRIPTION OF THE DRAWINGS

FIG. 1 is a schematic diagram of an illustrative electronic device with an image sensor that may include phase detection pixels in accordance with an embodiment of the present invention.

FIG. 2A is a cross-sectional view of illustrative phase detection pixels having photosensitive regions with different and asymmetric angular responses in accordance with an embodiment of the present invention.

FIGS. 2B and 2C are cross-sectional views of the phase detection pixels of FIG. 2A in accordance with an embodiment of the present invention.

FIG. 3 is a diagram of illustrative signal outputs of phase detection pixels for incident light striking the phase detection pixels at varying angles of incidence in accordance with an embodiment of the present invention.

FIG. 4 is a cross-sectional view of an illustrative image sensor with a phase detection pixel support structure in accordance with an embodiment of the present invention.

FIG. 5 is a cross-sectional view of an illustrative image sensor with a phase detection pixel support structure formed over a microlens in accordance with an embodiment of the present invention.

FIG. 6 is a cross-sectional view of an illustrative image sensor with a shaped phase detection pixel support structure in accordance with an embodiment of the present invention.

FIG. 7 is a cross-sectional view of illustrative steps for forming a phase detection pixel support structure in accordance with an embodiment of the present invention.

### DETAILED DESCRIPTION

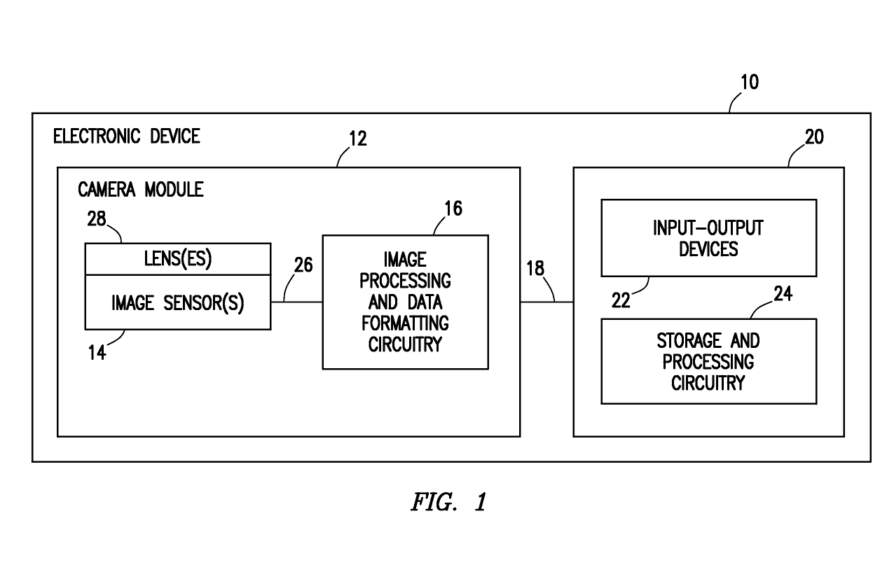

Embodiments of the present invention relate to image sensors with automatic focusing and depth sensing capabilities. An electronic device with a camera module is shown in FIG. 1. Electronic device 10 may be a digital camera, a computer, a cellular telephone, a medical device, or other electronic device. Camera module 12 (sometimes referred to as an imaging device) may include one or more image sensors 14 and one or more lenses 28. During operation, lenses 28 (sometimes referred to as optics 28) focus light onto image sensor 14. Image sensor 14 includes photosensitive elements (e.g., pixels) that convert the light into digital data. Image sensors may have any number of pixels (e.g., hundreds, thousands, millions, or more). A typical image sensor may, for example, have millions of pixels (e.g., megapixels). As examples, image sensor 14 may include bias circuitry (e.g., source follower load circuits), sample and hold circuitry, correlated double sampling (CDS) circuitry, amplifier circuitry, analog-to-digital (ADC) converter circuitry, data output circuitry, memory (e.g., buffer circuitry), address circuitry, etc.

Still and video image data from image sensor 14 may be provided to image processing and data formatting circuitry 16. Image processing and data formatting circuitry 16 may be used to perform image processing functions such as automatic focusing functions, depth sensing, data formatting, adjusting white balance and exposure, implementing video image stabilization, face detection, etc. For example, during automatic focusing operations, image processing and data formatting circuitry 16 may process data gathered by phase detection pixels in image sensor 14 to determine the magnitude and direction of lens movement (e.g., movement of lens 28) needed to bring an object of interest into focus.

Image processing and data formatting circuitry 16 may also be used to compress raw camera image files if desired (e.g., to Joint Photographic Experts Group or JPEG format). In a typical arrangement, which is sometimes referred to as a system on chip (SOC) arrangement, camera sensor 14 and image processing and data formatting circuitry 16 are implemented on a common integrated circuit. The use of a single integrated circuit to implement camera sensor 14 and image processing and data formatting circuitry 16 can help to reduce costs. This is, however, merely illustrative. If desired, camera sensor 14 and image processing and data formatting circuitry 16 may be implemented using separate integrated circuits.

Camera module 12 may convey acquired image data to host subsystems 20 over path 18 (e.g., image processing and data formatting circuitry 16 may convey image data to subsystems 20). Electronic device 10 typically provides a user with numerous high-level functions. In a computer or advanced cellular telephone, for example, a user may be provided with the ability to run user applications. To implement these functions, host subsystem 20 of electronic device 10 may include storage and processing circuitry 24 and input-output devices 22 such as keypads, input-output ports, joysticks, and displays. Storage and processing circuitry 24 may include volatile and nonvolatile memory (e.g., random-access memory, flash memory, hard drives, solid state drives, etc.). Storage and processing circuitry 24 may also include microprocessors, microcontrollers, digital signal processors, application specific integrated circuits, or other processing circuits.

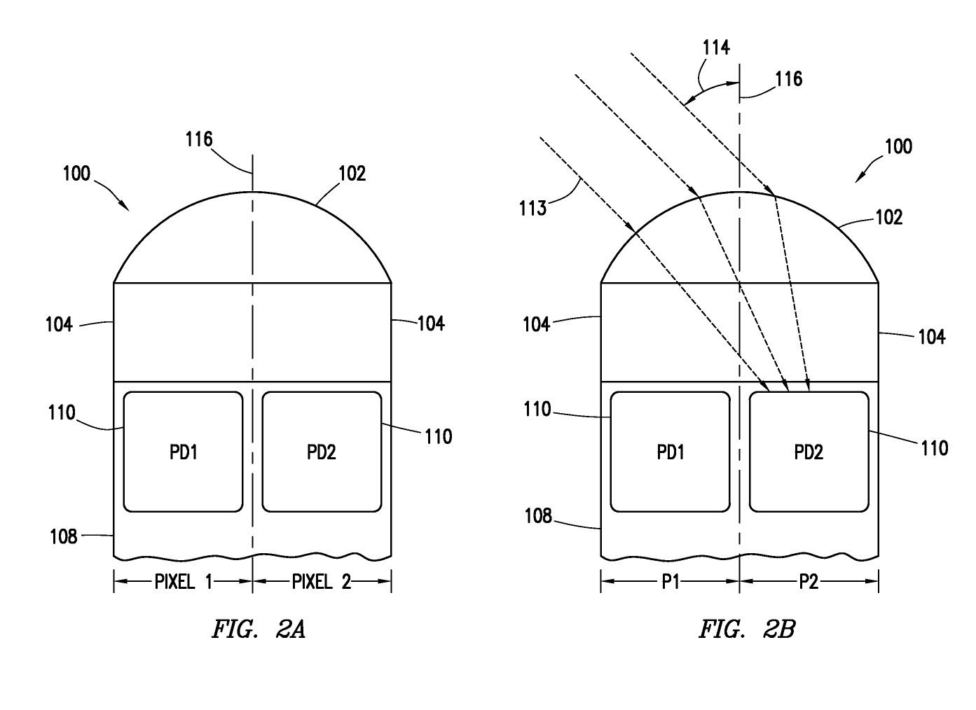

It may be desirable to provide image sensors with depth sensing capabilities (e.g., to use in automatic focusing applications, 3D imaging applications such as machine vision applications, etc.). To provide depth sensing capabilities, image sensor 14 may include phase detection pixel groups such as pixel pair 100 shown in FIG. 2A.

FIG. 2A is an illustrative cross-sectional view of pixel pair 100. Pixel pair 100 may include first and second pixels such as Pixel 1 and Pixel 2. Pixel 1 and Pixel 2 may include photosensitive regions 110 formed in a substrate such as silicon substrate 108. For example, Pixel 1 may include an associated photosensitive region such as photodiode PD1, and Pixel 2 may include an associated photosensitive region such as photodiode PD2. A microlens may be formed over photodiodes PD1 and PD2 and may be used to direct incident light towards photodiodes PD1 and PD2. The arrangement of FIG. 2A in which microlens 102 covers two pixel regions may sometimes be referred to as a 2×1 or 1×2 arrangement because there are two phase detection pixels arranged consecutively in a line. Microlens 102 may have a width and a length, with the length being longer than the width. Microlens 102 may have a length that is about twice as long as its width. Microlens 102 may be in the shape of an ellipse with an aspect ratio of about 2:1. In other embodiments, microlens 102 may be another shape such as a rectangle or another desired shape. Microlens 102 may have an aspect ratio of less than 2:1, 2:1, greater than 2:1, greater than 3:1, or any other desired aspect ratio.

Color filters such as color filter elements 104 may be interposed between microlens 102 and substrate 108. Color filter elements 104 may filter incident light by only allowing predetermined wavelengths to pass through color filter elements 104 (e.g., color filter 104 may only be transparent to the certain ranges of wavelengths). Photodiodes PD1 and PD2 may serve to absorb incident light focused by microlens 102 and produce pixel signals that correspond to the amount of incident light absorbed.

Photodiodes PD1 and PD2 may each cover approximately half of the substrate area under microlens 102 (as an example). By only covering half of the substrate area, each photosensitive region may be provided with an asymmetric angular response (e.g., photodiode PD1 may produce different image signals based on the angle at which incident light reaches pixel pair 100). The angle at which incident light reaches pixel pair 100 relative to a normal axis 116 (i.e., the angle at which incident light strikes microlens 102 relative to the optical axis 116 of lens 102) may be herein referred to as the incident angle or angle of incidence.

An image sensor can be formed using front side illumination imager arrangements (e.g., when circuitry such as metal interconnect circuitry is interposed between the microlens and photosensitive regions) or back side illumination imager arrangements (e.g., when photosensitive regions are interposed between the microlens and the metal interconnect circuitry). The example of FIGS. 2A, 2B, and 2C in which pixels 1 and 2 are backside illuminated image sensor pixels is merely illustrative. If desired, pixels 1 and 2 may be front side illuminated image sensor pixels. Arrangements in which pixels are backside illuminated image sensor pixels are sometimes described herein as an example.

In the example of FIG. 2B, incident light 113 may originate from the left of normal axis 116 and may reach pixel pair 100 with an angle 114 relative to normal axis 116. Angle 114 may be a negative angle of incident light. Incident light 113 that reaches microlens 102 at a negative angle such as angle 114 may be focused towards photodiode PD2. In this scenario, photodiode PD2 may produce relatively high image signals, whereas photodiode PD1 may produce relatively low image signals (e.g., because incident light 113 is not focused towards photodiode PD1).

In the example of FIG. 2C, incident light 113 may originate from the right of normal axis 116 and reach pixel pair 100 with an angle 118 relative to normal axis 116. Angle 118 may be a positive angle of incident light. Incident light that reaches microlens 102 at a positive angle such as angle 118 may be focused towards photodiode PD1 (e.g., the light is not focused towards photodiode PD2). In this scenario, photodiode PD2 may produce an image signal output that is relatively low, whereas photodiode PD1 may produce an image signal output that is relatively high.

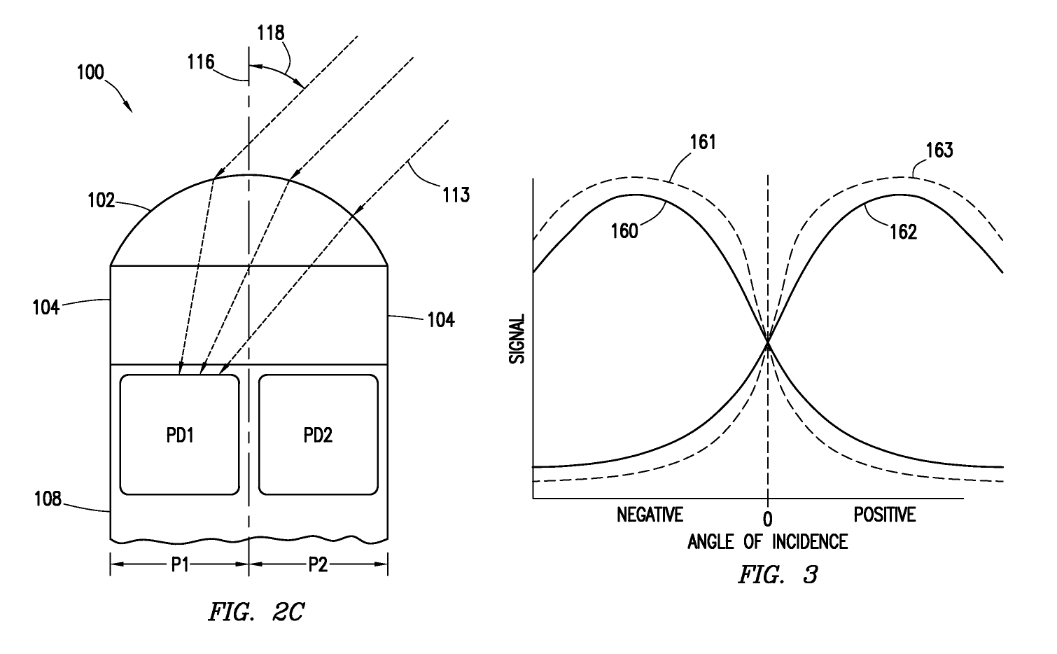

The positions of photodiodes PD1 and PD2 may sometimes be referred to as asymmetric positions because the center of each photosensitive area 110 is offset from (i.e., not aligned with) optical axis 116 of microlens 102. Due to the asymmetric formation of individual photodiodes PD1 and PD2 in substrate 108, each photosensitive area 110 may have an asymmetric angular response (e.g., the signal output produced by each photodiode 110 in response to incident light with a given intensity may vary based on an angle of incidence). In the diagram of FIG. 3, an example of the pixel signal outputs of photodiodes PD1 and PD2 of pixel pair 100 in response to varying angles of incident light is shown.

Line 160 may represent the output image signal for photodiode PD2 whereas line 162 may represent the output image signal for photodiode PD1. For negative angles of incidence, the output image signal for photodiode PD2 may increase (e.g., because incident light is focused onto photodiode PD2) and the output image signal for photodiode PD1 may decrease (e.g., because incident light is focused away from photodiode PD1). For positive angles of incidence, the output image signal for photodiode PD2 may be relatively small and the output image signal for photodiode PD1 may be relatively large.

The size and location of photodiodes PD1 and PD2 of pixel pair 100 of FIGS. 2A, 2B, and 2C are merely illustrative. If desired, the edges of photodiodes PD1 and PD2 may be located at the center of pixel pair 100 or may be shifted slightly away from the center of pixel pair 100 in any direction. If desired, photodiodes 110 may be decreased in size to cover less than half of the pixel area.

Output signals from pixel pairs such as pixel pair 100 may be used to adjust the optics (e.g., one or more lenses such as lenses 28 of FIG. 1) in camera module 12 during automatic focusing operations. The direction and magnitude of lens movement needed to bring an object of interest into focus may be determined based on the output signals from pixel pairs 100.

For example, by creating pairs of pixels that are sensitive to light from one side of the lens or the other, a phase difference can be determined. This phase difference may be used to determine both how far and in which direction the image sensor optics should be adjusted to bring the object of interest into focus.

When an object is in focus, light from both sides of the image sensor optics converges to create a focused image. When an object is out of focus, the images projected by two sides of the optics do not overlap because they are out of phase with one another. By creating pairs of pixels where each pixel is sensitive to light from one side of the lens or the other, a phase difference can be determined. This phase difference can be used to determine the direction and magnitude of optics movement needed to bring the images into phase and thereby focus the object of interest. Pixel groups that are used to determine phase difference information such as pixel pair 100 are sometimes referred to herein as phase detection pixels or depth-sensing pixels.

A phase difference signal may be calculated by comparing the output pixel signal of PD1 with that of PD2. For example, a phase difference signal for pixel pair 100 may be determined by subtracting the pixel signal output of PD1 from the pixel signal output of PD2 (e.g., by subtracting line 162 from line 160). For an object at a distance that is less than the focused object distance, the phase difference signal may be negative. For an object at a distance that is greater than the focused object distance, the phase difference signal may be positive. This information may be used to automatically adjust the image sensor optics to bring the object of interest into focus (e.g., by bringing the pixel signals into phase with one another).

In some scenarios, it may be advantageous to increase the asymmetric angular response of PD1 and PD2. Lines 161 and 163 may represent the output image signal for photodiode PD2 and PD1, respectively, for photodiodes with increased angular response compared to lines 160 and 162. As shown in FIG. 3, the difference between lines 161 and 163 is greater than the difference between lines 160 and 162. The photodiodes associated with lines 161 and 163 may therefore generate phase detection data with a higher sensitivity than the photodiodes associated with lines 160 and 162. In general, an increased asymmetric angular response in PD1 and PD2 will improve the quality of the phase detection data generated. One way to increase the asymmetric angular response in PD1 and PD2 is for the phase detection pixels to have an increased stack height. More separation between a phase detection pixel's photodiode and lens may result in an increased asymmetric angular response in the pixel. However, conventional image sensors may have image pixels and phase detections pixels with the same stack height. In these scenarios, increasing stack height may not be desirable as increasing the stack height of the image pixels may reduce the quality of the image data obtained by the image pixels. It is often desirable to minimize the stack height of image pixels to reduce their signal degradation with increasing incident light angle. A minimized stack height in image pixels may reduce artifacts and lead to higher quality image pixel data.

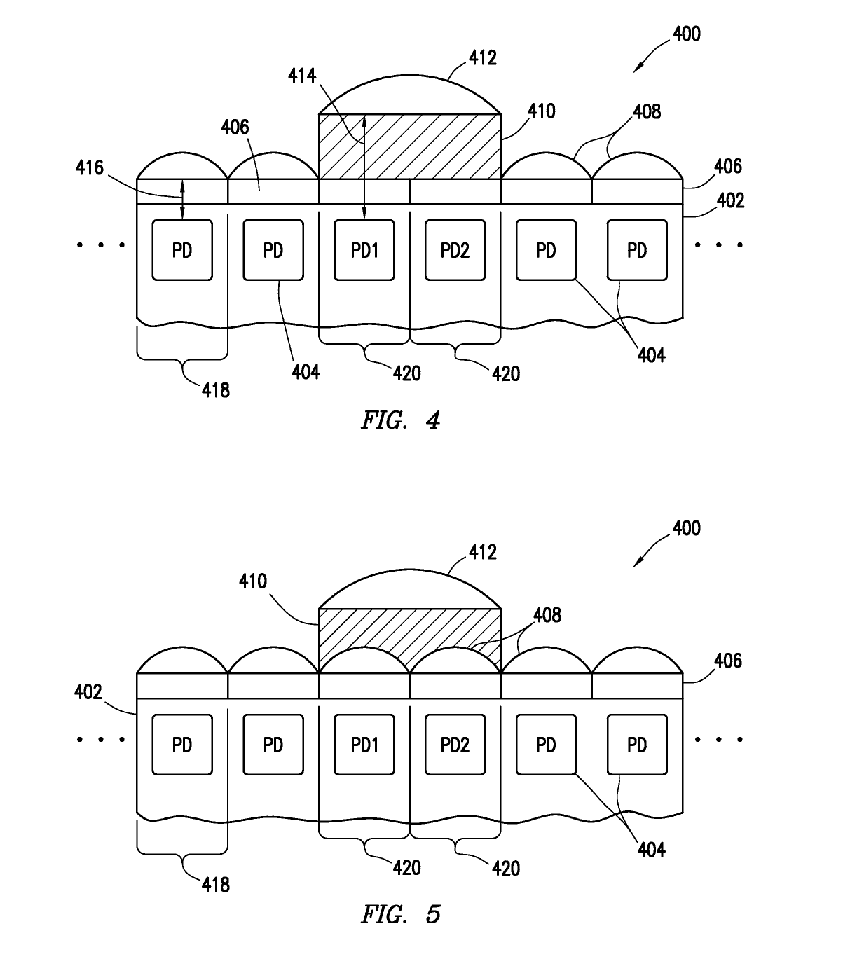

In order to include both image pixels and phase detection pixels in a single image sensor while optimizing the quality of both the phase detection data and the image pixel data, image sensors may be formed that include pedestals for phase detection pixels. FIG. 4 is a cross-sectional view of an illustrative image sensor with a phase detection pixel pedestal. Image sensor 400 may include substrate 402. Substrate 402 may be a silicon substrate similar to substrate 108 in FIG. 2A. Photosensitive regions such as photodiodes 404 may be formed in substrate 402. Imaging pixels such as imaging pixel 418 may include one photodiode that is covered by a respective microlens 408. Phase detection pixels 420 may include two photodiodes that are covered by a respective microlens 412.

Both imaging pixels 418 and phase detection pixels 420 may include color filter elements 406 interposed between their respective microlenses and substrate 402. Color filter elements 406 may filter incident light by only allowing predetermined wavelengths to pass through color filter elements 406 (e.g., color filter 406 may only be transparent to certain ranges of wavelengths). Color filter elements 406 may be arranged in a color filter array with a known pattern such as the Bayer color filter pattern.

The phase detection pixels may include pedestal 410 (sometimes referred to herein as support structure, base structure, support, and base) that separates microlens 412 from the color filter array. The added thickness of pedestal 410 may result in phase detection pixels 420 having a stack height 414. Stack height 414 may be greater than stack height 416 of imaging pixels 418. Stack heights 414 and 416 may be any desired height (e.g., less than 0.2 μm, less than 0.4 μm, less than 1.0 μm, 1.0 μm, greater than 1.0 μm, greater than 10 μm, etc.). Support structure 410 may be any desired thickness (e.g., less than 0.2 μm, less than 0.4 μm, less than 1.0 μm, 1.0 μm, greater than 1.0 μm, greater than 10 μm, etc.). The pedestal may result in the phase detection pixels having an increased asymmetric angular response and improve the quality of the phase detection data. Because support structure 410 is only positioned under the phase detection pixels, imaging pixels 418 may have a smaller stack height that results in high quality image data.

Pedestal 410 may be formed from any desired material. In certain embodiments, support structure 410 may be a clear polymer that is transparent to all wavelengths of light. In other embodiments, support structure 410 may be a color filter element. Pedestal 410 may filter incident light by only allowing predetermined wavelengths to pass through support structure 410 (e.g., support structure 410 may only be transparent to certain ranges of wavelengths). Pedestal 410 may supplement or replace the color filter elements 406 of phase detection pixels 420. Embodiments where base structure 410 filters color may help flatten through color response and reduce the complexity of the algorithm needed to correct the artifacts caused by the phase detection pixels. Support structure 410 may filter any desired color. Support structure 410 may be the same color as the color filter interposed between the pedestal and substrate 402. Alternatively, support structure 410 may be a different color than the color filter element interposed between the pedestal and substrate 402. In certain embodiments, support structure 410 may replace the underlying color filter element entirely. In these embodiments, support structure 410 may be disposed directly on the surface of substrate 402.

Support structure 410 may be formed using any desired process such as a photolithographic process using a positive or negative photoresist. First, the image sensor may be coated with a photoresist layer. In embodiments where a positive photoresist is used, light may be selectively applied to the portions of the photoresist that cover the imaging pixels. A mask may be used to cover the phase detection pixels and prevent the portions of the photoresist that cover the phase detection pixels from being exposed to light. The photoresist may then be exposed to a photoresist developer. The portion that was exposed to light (e.g., the photoresist covering the imaging pixels) may be soluble when exposed to the developer. The masked portion (e.g., the photoresist covering the phase detection pixels) may remain insoluble when exposed to the developer. In this example, only the photoresist covering the phase detection pixels will remain. This remaining photoresist may be cured to form base structure 410.

In other embodiments, a negative photoresist may be used to coat the image sensor. In these embodiments, a mask may be used to cover the imaging pixels while leaving the phase detection pixels exposed. When light is applied to the photoresist, the negative photoresist may become insoluble to the photoresist developer. Because only the portions of the photoresist covering the phase detection pixels are uncovered by the mask, only the photoresist covering the phase detection pixel will be insoluble to the developer. When the developer is applied, only the photoresist that covers the phase detection pixels will remain. This layer may be cured to form pedestal 410.

The description of forming pedestal 410 using photolithography is purely illustrative. Pedestal 410 may be formed using photolithography or any other desired method.

FIG. 4 shows support structure 410 disposed directly on color filter elements 406 without an underlying microlens. In these embodiments, the array of microlenses may omit microlenses 406 over the phase detection pixels. However, this example is purely illustrative. In certain cases, support structure 410 may be formed over preexisting microlenses. FIG. 5 is a cross-sectional view of an illustrative image sensor with a phase detection pixel pedestal formed over a microlens. As shown, base structure 410 may cover microlenses 408. In these embodiments, the microlenses may be formed using standard processes, with microlenses covering the entire array of pixels. Pedestals 410 are then formed over the preexisting microlenses.

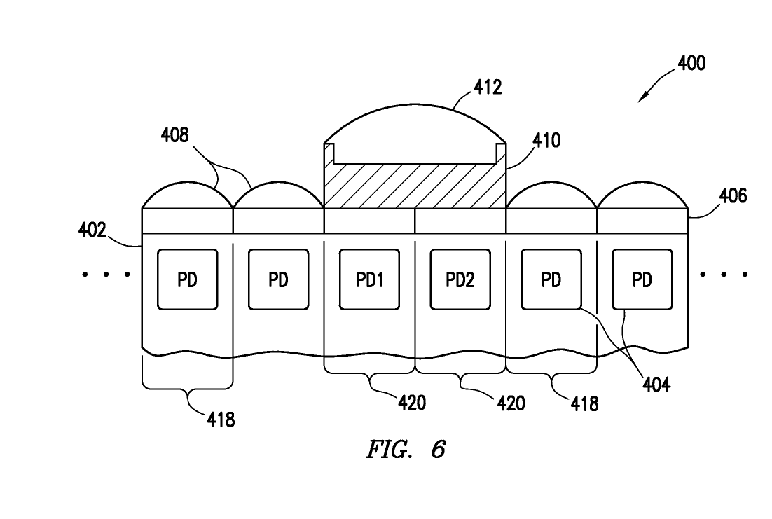

FIG. 6 is a cross-sectional view of an illustrative image sensor with a shaped phase detection pixel pedestal. As shown, support structure 410 may be shaped in a non-uniform manner to optimize the shape of phase detection lens 412. Pedestal 410 may have varying height as shown by the taller portion at the periphery of pedestal 410 compared to the central portion of pedestal 410. The length and width of support 410 may also be non-uniform. Pedestal 410 may be a rectangle, a circle, or any other desired shape. The shape of pedestal 410 in FIG. 6 is purely illustrative. The irregular shape of pedestal 410 may increase the stability of phase detection lens 412. The shape of pedestal 410 may also shape lens 412 to optimize the performance of lens 412.

In FIG. 6, base structure 410 is shown as being formed directly on color filter array 406 without an underlying microlens. This arrangement is similar to the arrangement shown in FIG. 4. However, this example is purely illustrative, and if desired shaped support structure 410 may be formed over microlenses 408 as shown in FIG. 5.

The irregular shape of pedestal 410 in FIG. 6 may be formed using any desired methods. In one embodiment, a gray tone mask may be used during a photolithography process. A gray tone mask may allow varying amounts of light through the mask during the light exposure step of photolithography. This may allow the pedestal to have varying heights depending on how much light was exposed to each area of the pedestal. In another embodiment, multiple photoresists may be used to form shaped support structure 410. For example, a first photoresist may be used to form a central portion of support structure 410 with a uniform height. A second photoresist may then be used to form the peripheral portion of support structure 410 that has a greater height than the central portion of support structure 410.

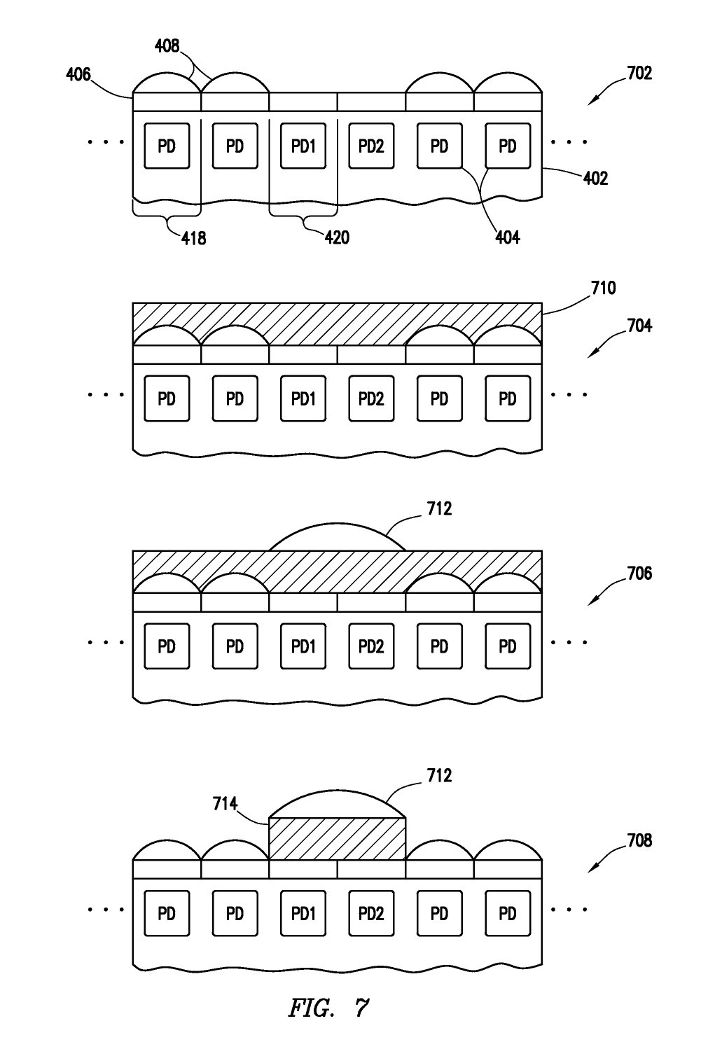

FIG. 7 is a cross-sectional view of illustrative steps for forming a phase detection pixel pedestal. At step 702, an image sensor may be provided that includes image pixels 418 and phase detection pixels 420. Each pixel may have a photodiode 404 formed in substrate 402. The image sensor may also include color filter elements 406 and microlenses 408 formed over the imaging pixels. In this embodiment, microlenses are shown as formed over only the imaging pixels, similar to the embodiments of FIGS. 4 and 6. However, this example is purely illustrative and microlenses may be included that cover the entire array as shown in FIG. 5. In certain embodiments, the image sensor may be coated with an anti-reflective layer at step 702. The anti-reflective layer may be any desired material and may be deposited using any desired method such as chemical vapor deposition (CVD).

At step 704, the image sensor is coated uniformly with layer 710. The layer may be cured to form a rigid surface. Pedestal layer 710 may be formed from any desired material. In certain embodiments, support structure layer 710 may be a clear polymer that is transparent to all wavelengths of light. In other embodiments, pedestal layer 710 may be a color filter element. Pedestal layer 710 may filter incident light by only allowing predetermined wavelengths to pass through pedestal layer 710 (e.g., pedestal layer 710 may only be transparent to certain ranges of wavelengths). Pedestal layer 710 may supplement or replace the color filter elements 406 of phase detection pixels 420.

At step 706, phase detection lens 712 may be formed on support structure layer 710. Phase detection lens 712 may be formed using any desired method. For example, phase detection lens 712 may be formed by depositing a photo patternable polymeric compound on support structure layer 710. The polymeric compound may then be patterned and reflowed to form the desired lens shape. However, this example is purely illustrative and any other desired method may be used to form phase detection lens 712.

At step 708, the portions of support structure layer 710 that cover imaging pixels 418 may be removed, resulting in support structure 714 with phase detection lens 712 covering the phase detection pixels. The portions of pedestal layer 710 that cover the imaging pixels may be removed using any desired method. For example, the pedestal layer may undergo anisotropic etching outside of the phase detection pixel areas. Any other desired etching technique may be used such as wet etching or plasma etching. Support structure 714 may be masked during the etching process to prevent any loss of material in the pedestal. The process illustrated in FIG. 7 may reduce the likelihood of coat streaks during the spin coat step performed while forming the phase detection lens.

In the previous examples, phase detection pixels are described that include a pair of phase detection pixels covered by a single microlens. The support structure may be used to raise the stack height of the phase detection pixel pair. It should be noted that the example of a phase detection pixel pair covered by a single microlens is purely illustrative. A support structure may be used to increase the stack height of any pixel that may be used to gather phase detection information. For example, the support structure may be used to increase the stack height of pixels with metal apertures. The phase detection pixels also do not have to be adjacent as depicted in FIGS. 2-7. A support structure may be used to increase the stack height of non-adjacent phase detection pixels. For example, a phase detection pixel may be separated from a corresponding phase detection pixel by one intervening pixel, two intervening pixels, or more than two intervening pixels. The support structure may also be used to increase the stack height of more than two adjacent pixels. For example, three, four, or more than four phase detection pixels may be arranged consecutively in a line. In another arrangement, phase detection pixels may be arranged in square groups (e.g., 2×2 arrangement, 3×3 arrangement, etc.). The stack height of any arrangement of phase detection pixels may be increased by the use of a support structure.

The height of the phase detection pixel pedestals may be uniform across the image sensor. For example, an image sensor may have a number of phase detection pixels arranged throughout the pixel array. The phase detection pixels may be scattered randomly throughout the array or be arranged in rows, columns, interrupted rows, interrupted columns, or any other desired arrangement. In these cases, the phase detection pixel support structure for each phase detection pixel may have the same height. Alternatively, the height of the pedestals may vary across the array.

Various embodiments have been described illustrating an image sensor with a pixel array. The pixel array may include a plurality of image pixels that gather image data and a plurality of phase detection pixels that gather phase detection data. Each phase detection pixel may have a respective photosensitive area. The pixel array also may include a plurality of support structures and a color filter array with a plurality of color filter elements. Each photosensitive area may be covered by a respective color filter element, and the respective color filter element of each phase detection pixel may be covered by at least a portion of a support structure.

At least a portion of a microlens may be formed on a top surface of each support structure. The plurality of phase detection pixels may be arranged in pairs that include first and second phase detection pixels with different angular responses. Each pair of phase detection pixels may be covered by a single microlens. Each pair of phase detection pixels may be covered by a respective support structure. Each support structure may be formed directly on the color filter array without an intervening microlens. Each phase detection pixel may have a respective microlens that covers each respective photosensitive area. Each respective microlens may be covered by the respective portion of the support structure. At least one support structure may have a planar top surface. At least one support structure may have a first height at a first portion of the support structure and a second height at a second portion of the support structure, where the first and second heights are different. At least one support structure may include a color filter element.

In various embodiments, an image sensor may include a pixel array. The pixel array may include a plurality of image pixels that gather image data and a plurality of phase detection pixels that gather phase detection data. The plurality of image pixels may have a first stack height. The plurality of phase detection pixels may have a second stack height. The second stack height may be greater than the first stack height.

Each pixel in the plurality of image pixels and the plurality of phase detection pixels may have a respective photodiode covered by a respective color filter element. The pixel array may include a support structure layer that covers only the plurality of phase detection pixels. The support structure layer may include a plurality of color filter elements. The plurality of image pixels may be covered by a plurality of respective color filter elements with a first thickness and the plurality of phase detection pixels may be covered by a plurality of respective color filter elements with a second thickness, where the second thickness is greater than the first thickness.

In various embodiments, a method may include forming photodiodes in a substrate and forming a color filter array over the substrate. The color filter array may include a plurality of color filter elements, with each color filter element covering a respective photodiode. The method may include forming microlenses on at least a first portion of the color filter elements and forming a pedestal layer over at least a second portion of the color filter elements. Forming the pedestal layer may include covering the entire color filter array with a pedestal material and forming at least one phase detection lens on a surface of the pedestal material. Forming the pedestal layer may include selectively removing the pedestal material that is not covered by the at least one phase detection lens. Forming the pedestal layer may include forming the pedestal layer using a positive photoresist or a negative photoresist.

The foregoing is merely illustrative of the principles of this invention and various modifications can be made by those skilled in the art. The foregoing embodiments may be implemented individually or in any combination.

What is claimed is:

1. An image sensor having a pixel array, wherein the pixel array comprises:
a plurality of image pixels that gather image data;
a plurality of phase detection pixels that gather phase detection data, wherein each phase detection pixel has a respective photosensitive area;
a plurality of support structures; and
a color filter array with a plurality of color filter elements, wherein each photosensitive area is covered by a respective color filter element, wherein the respective color filter element of each phase detection pixel is covered by at least a portion of a support structure.

2. The image sensor defined in claim 1, wherein at least a portion of a microlens is formed on a top surface of each support structure.

3. The image sensor defined in claim 1, wherein the plurality of phase detection pixels is arranged in pairs that include first and second phase detection pixels with different angular responses.

4. The image sensor defined in claim 3, wherein each pair of phase detection pixels is covered by a single microlens.

5. The image sensor defined in claim 4, wherein each pair of phase detection pixels is covered by a respective support structure.

6. The image sensor defined in claim 1, wherein each support structure is formed directly on the color filter array without an intervening microlens.

7. The image sensor in claim 1, wherein each phase detection pixel has a respective microlens that covers each respective photosensitive area, and wherein each respective microlens is covered by the respective portion of the support structure.

8. The image sensor in claim 1, wherein at least one support structure has a planar top surface.

9. The image sensor in claim 1, wherein at least one support structure has a first height at a first portion of the support structure and a second height at a second portion of the support structure, and wherein the first height and the second height are different.

10. The image sensor defined in claim 1, wherein at least one support structure comprises a color filter element.

11. An image sensor having a pixel array, wherein the pixel array comprises:
a plurality of image pixels that gather image data, wherein the plurality of image pixels has a first stack height; and
a plurality of phase detection pixels that gather phase detection data, wherein the plurality of phase detection pixels has a second stack height, and wherein the second stack height is greater than the first stack height.

12. The image sensor defined in claim 11, wherein each pixel in the plurality of image pixels and the plurality of phase detection pixels has a respective photodiode covered by a respective color filter element.

13. The image sensor defined in claim 12, wherein the pixel array comprises a support structure layer that covers only the plurality of phase detection pixels.

14. The image sensor defined in claim 13, wherein the support structure layer comprises a plurality of color filter elements.

15. The image sensor defined in claim 11, wherein the plurality of image pixels are covered by a plurality of respective color filter elements with a first thickness, and wherein the plurality of phase detection pixels are covered by a plurality of respective color filter elements with a second thickness, and wherein the second thickness is greater than the first thickness.

16. A method, comprising:
forming photodiodes in a substrate;
forming a color filter array over the substrate, wherein the color filter array comprises a plurality of color filter elements, and wherein each color filter element covers a respective photodiode;
forming microlenses on at least a first portion of the color filter elements; and
forming a pedestal layer over at least a second portion of the color filter elements.

17. The method defined in claim 16, wherein forming the pedestal layer comprises covering the entire color filter array with a pedestal material.

18. The method defined in claim 17, wherein forming the pedestal layer further comprises forming at least one phase detection lens on a surface of the pedestal material.

19. The method defined in claim 18, wherein forming the pedestal layer further comprises selectively removing the pedestal material that is not covered by the at least one phase detection lens.

20. The method defined in claim 16, wherein forming the pedestal layer comprises forming the pedestal layer using a photoresist selected from the group consisting of: a positive photoresist and a negative photoresist.
